(19) United States
(12) Patent Application Publication
(10) Pub. No.: US 2015/0175413 A1
(43) Pub. Date: Jun. 25, 2015

(54) Method and System to Control the Mechanical Stiffness of Nanoscale Components by Electrical Current Flow

(71) Applicant: The Provost, Fellows, Foundation Scholars, & the other members of Board, of the college of the Holy, Dublin (IE)

(72) Inventors: John Boland, Dublin (IE); Eoin McCarthy, Dublin (IE)

(21) Appl. No.: 14/540,564

(22) Filed: Nov. 13, 2014

(30) Foreign Application Priority Data
Nov. 13, 2013 (GB) 1320028.2

(51) Int. Cl. B81C 1/00

(52) U.S. Cl. CPC B81C 1/00658

(57) ABSTRACT

The invention provides a method and system to control the mechanical stiffness of a nanoscale component comprising the steps of applying a current to the nano-scale component; and increasing or decreasing the mechanical stiffness of the material by controlling the current flow applied to the component. The invention also provides a NanoElectroMechanical (NEMs) device comprising a controlled mechanical stiffness.

### FIELD

This invention describes a method and system to control the mechanical properties of individual nanoscale materials or components.

### BACKGROUND

NanoElectroMechanical (NEMs) devices are growing in importance as the ability to fabricate increasingly smaller structures continues in parallel with the miniaturisation of integrated circuits. All NEMs devices suffer from the problem of adhesion. Smaller features have by virtue of their size have relatively larger surface areas which increases the level of adhesion between assembled components. FIG. 1 shows the example of a NEMs switch. Such switches are being incorporated into CMOS technology to provide hard-off elements that can shut large number of conventional CMOS devices.

Conventional CMOS devices leak significant current even in the off state and hence limit battery life in mobile device. At present the scaling to smaller sizes of these devices is unattractive to the industry. The reason is that once the mechanical beam (black graphene beam in this example) is forced to bend down to make contact with the electrode beneath (by the application of the gate voltage) the adhesion between the beam and the contact is so great that it will not pop back into the neutral position after the gate voltage is removed. The adhesion is so great that the mechanical energy stored in the deflected beam is insufficient to overcome it. This is but one example. Adhesion is a pervasive problem in NEMS and is limited by the mechanical energy that can be stored in any nanoscale material.

NEMs technology is in danger of being deemed unscalable if the adhesion problem is not overcome. The general solution is to coat the nanoscale components with layers that minimise adhesion. In the case of NEMS switches this tends to be unworkable since these coatings must also be electrically conducting and conductive materials tend to result in high adhesion levels.

It is therefore an object to provide a system and method to overcome at least one of the above mentioned problems.

### SUMMARY

According to the invention there is provided, as set out in the appended claims, a method to control the mechanical stiffness of a nanoscale component comprising the steps of:
applying a current to the nanoscale component;
increasing or decreasing the mechanical stiffness of the material by controlling the current flow applied to the component.

Normally the stiffness of a material is determined by the bond strength between the atoms that make up the material. Engineers describe the mechanical properties of materials by various parameters such as the Young's modulus, and the bulk and shear moduli. These moduli are all related to each other and determined fundamentally by the strength of the bonding interaction between the atoms in the solid. The stiffness of any material of a given shape is invariant. The energy required to deform the material a given amount and thus the energy that can be stored in the materials is fixed.

The invention demonstrates that for specifically structured materials (e.g. a pentagonally twinned Ag nanowire) it is possible to increase the mechanical stiffness of the material by current flow. Therefore not only can the fundamental mechanical properties be tuned by current flow, but the energy stored (or spring constant) of a deformed materials beam can be increased by increasing the current flow through it. Thus specially structured nanoscale materials have potential in a wide range of NEMs applications.

This invention shows that it is possible to enhance the effective Youngs modulus of a material by applying a voltage so as to effect the passage of current through it. In the case of the NEMs switch this current flow automatically happens when the beam engages the contact. The energy stored in this beam now greatly exceeds that of the original beam and so it is possible for the stored energy to assist in the mechanical release. Note the change in beam stiffness is communicated at the speed of sound and so the beam will remain stiff for some time after the current flow ceases.

It will be appreciated that an engineered beam can be made of a dielectric with embedded wires or components. This enables a broad range of materials provide access to a wide range of stiffnesses. It is envisaged that positioning nanoscale wires into a dielectric makes it possible to engineer macroscopic beams for incorporation in larger devices.

In one embodiment there is provided the step of increasing the energy stored in the component by increasing the current flowing through it.

In one embodiment the energy stored can be represented by a spring constant value.

In one embodiment the energy stored exceeds that of the original component, such that the stored energy can assist in the mechanical release of the component when acting as a switch.

In one embodiment the current applied is an alternating current (AC) current.

In one embodiment the current applied is a direct current (DC) current.

In a further embodiment there is provided a system for controlling the mechanical stiffness of a nanoscale component comprising:
a source for applying a current to the nanoscale component;
a controller for increasing or decreasing the mechanical stiffness of the material by controlling the current flow applied to the component.

In one embodiment the controller is configured to control the energy stored in the component by increasing the current flowing through the component.

In one embodiment the energy stored can be represented by a spring constant value.

In one embodiment the energy stored exceeds that of the original component, such that the stored energy is configured to assist in the mechanical release of the component when acting as a switch.

In one embodiment the nanoscale component comprises a NanoElectroMechanical (NEMs) device.

In another embodiment there is provided a NanoElectroMechanical (NEMs) device comprising a controlled mechanical stiffness. In one embodiment the mechanical stiffness is controlled by an applied current.

In a further embodiment there is provided a method to control the mechanical stiffness of a nanoscale component comprising the steps of:
applying a voltage to or across the nanoscale component;
increasing or decreasing the mechanical stiffness of the material by controlling the voltage applied to the component.

In another embodiment of the invention there is provided a system for controlling the mechanical stiffness of a nanoscale component comprising:
a source for applying a voltage to the nanoscale component;
a controller for increasing or decreasing the mechanical stiffness of the material by controlling the voltage applied to the component.

### BRIEF DESCRIPTION OF THE DRAWINGS

The invention will be more clearly understood from the following description of an embodiment thereof, given by way of example only, with reference to the accompanying drawings, in which:

FIG. 1A illustrates Bridged and FIG. 1B cantilever architecture of a NEMs device;

FIG. 2A illustrates a device where the invention is applied and FIG. 2B displays the results obtained;

FIG. 3 illustrates the relative change in stiffness as a function of current density for several silver nanowires with radii between 32-39 nm.

FIG. 4 illustrates a five-fold twin planes in Ag nanowires. FIG. 4A side view, FIG. 4B wire cross section;

FIG. 5 illustrates the change in stiffness as a function of current density for an individual 40 nm nickel nanowire;

FIG. 6 illustrates data on Au NWs with pentagonal twinned structure.

FIG. 6A Force-displacement curves showing increase in stiffness with increased current density. FIG. 6B Values of Young's modulus or stiffness derived from the data in A;

FIG. 7 shows a 3D perspective view of a cylindrical beam with a number of wires embedded partially or wholly along its length; and

FIG. 8 illustrates a schematic system to measure the change in stiffness of individual silver nanowires.

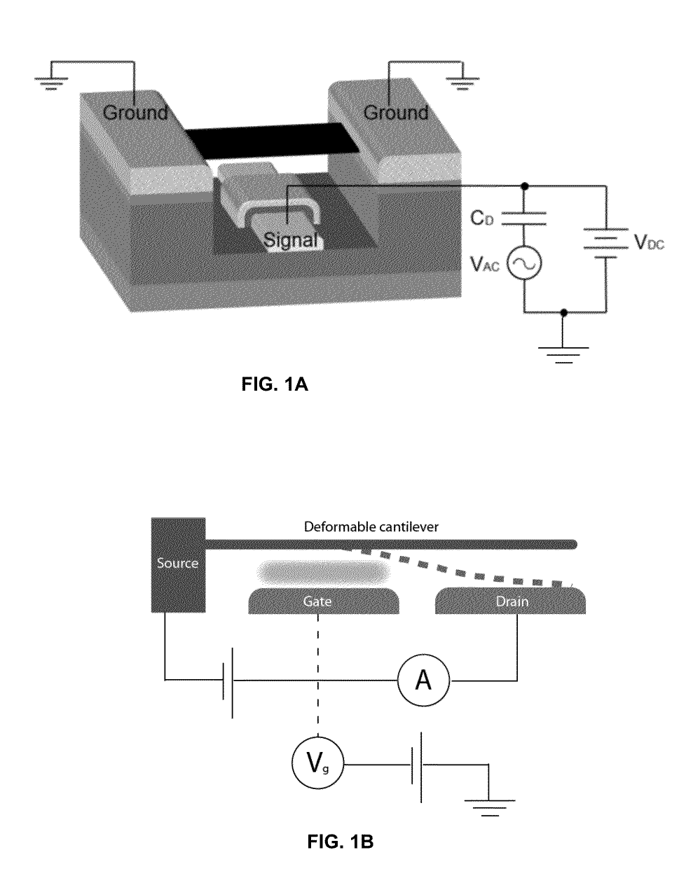

### DETAILED DESCRIPTION OF THE DRAWINGS

In general the mechanical energy stored in any material is proportional to its stiffness. The appropriate measure of stiffness depends on the type of deformation involved (tensile, bending or shear). In the case of bending or tension the materials stiffness is measured by its Young modulus, which is fundamentally dependent on the inherent bonding properties of the material. Enhanced stiffness requires control of the nanostructure within the beam.

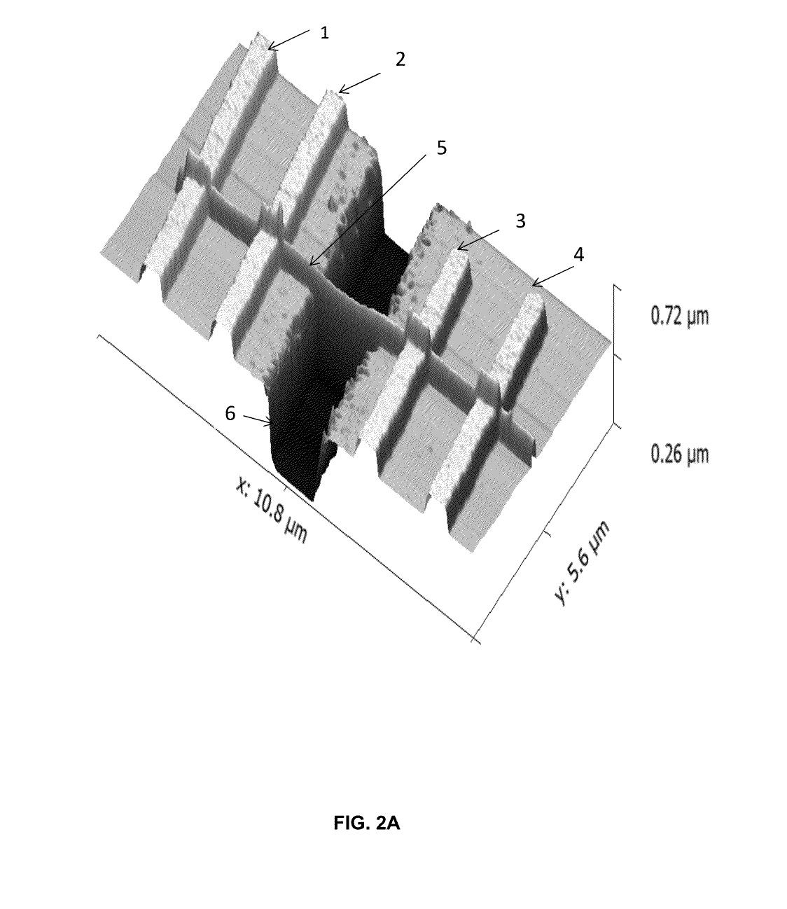

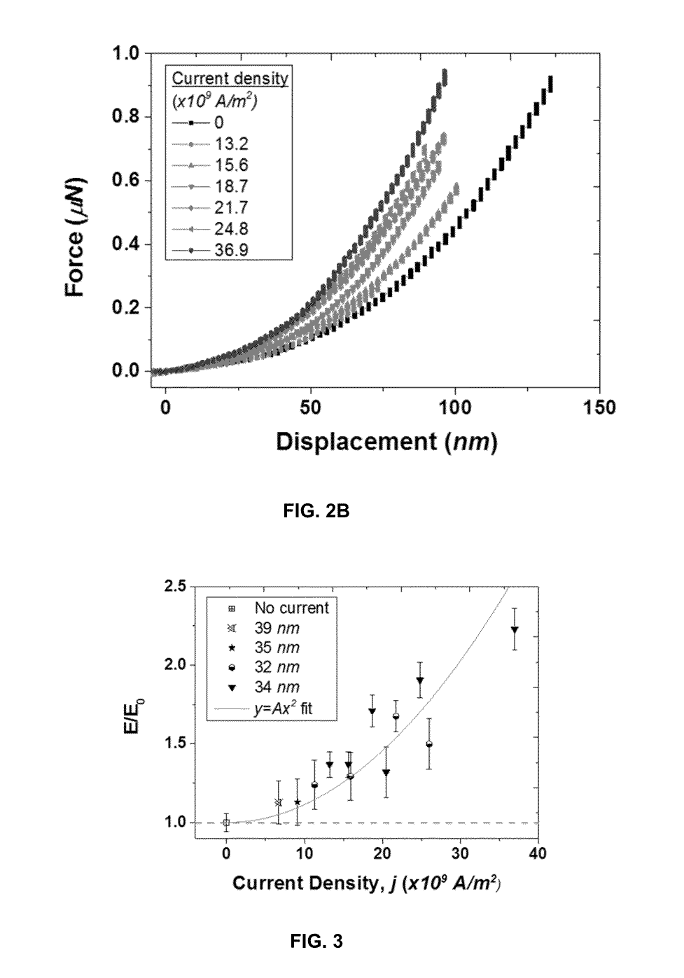

FIG. 2A is a 3D rendered AFM image of an individual suspended silver nanowire. The four electrical contacts are also evident. FIG. 2B illustrates an array of force-displacement curves for an individual 34 nm radius silver nanowire as a function of current density.

The method of the invention is demonstrated for a device, as shown in FIG. 2A comprised of an individual pentagonally twinned silver nanowire 5 that is suspended above a trench 6, fabricated on an insulating surface, and electrically contacted with four metallic contacts 1-4. The stiffness of the wire 5 is shown to scale with the current that passes thought the wire, thereby providing electrical control of the mechanical properties of the wire 5. This current stiffening behaviour is not found in macroscopic materials nor is it found in nanoscale materials that do not have controlled twinning planes or internal interfaces to control the current flow.

FIG. 2B displays the results for an individual 34 nm radius Ag nanowire elastically loaded under increasing current densities. The current is induced by applying a voltage across the outer two electrodes, labelled 1 and 4 in FIG. 2A. From FIG. 2B, the curvature of each force-displacement (f-d) curve increases, and hence the stiffness increases, with each incremental increase in current density, j. The current density was calculated from j=I/A, where I is the current passing through the wire and A is the wire cross sectional area. The modulus increases with the amount of charge that is passed through; hence, an increase in the current density acts to stiffen the nanowire.

Several silver nanowires between 32-39 nm in radius were analysed using this technique. FIG. 3 illustrates the relative change in stiffness as a function of current density for each silver nanowire. The effect is specific to wires with a specially controlled internal structure, in this case a pentagonal twinning of the grain structure along the axis of the wire. This confirms current induced stiffening was observed across all the specimens examined.

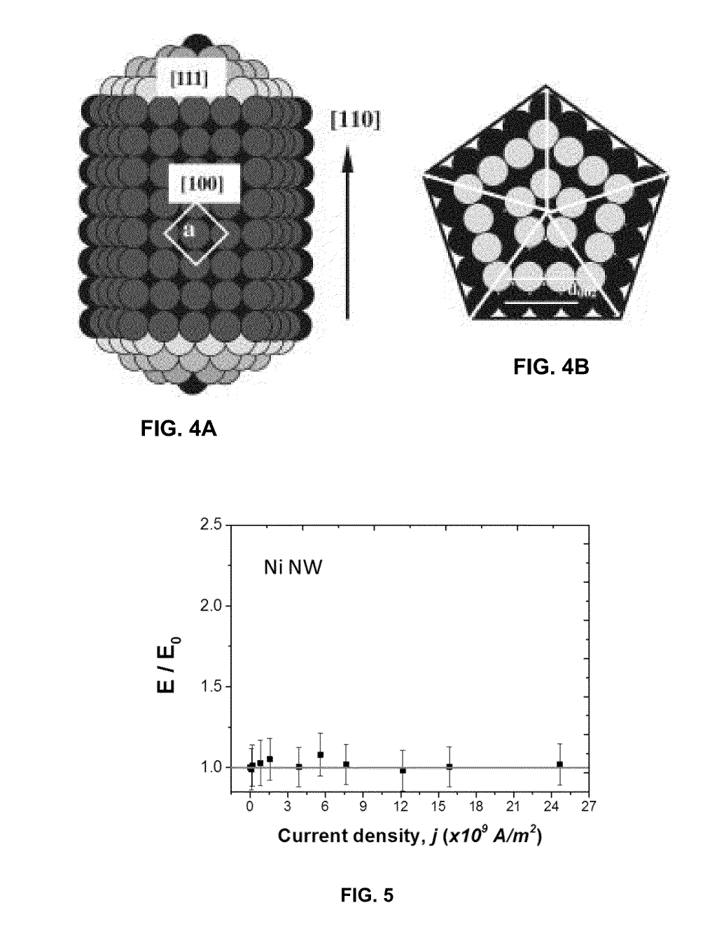

FIG. 4 illustrates a five-fold twin planes in Ag nanowires. FIG. 4A side view, FIG. 4B wire cross section.

FIG. 5 displays the current density dependent modulus of an individual 40 nm radius nickel nanowires, which does not have this internal twinning structure. There is no evidence of an increase in modulus observed for nickel nanowires at current densities comparable to that used in the same measurement on silver nanowires, shown in FIG. 3. The crystallographic structure of nickel nanowires is polycrystalline, with randomly oriented grains along the length of the wire, whereas silver nanowires are single crystals with five-fold twinning along their length. No current induced enhancement of stiffness is observed.

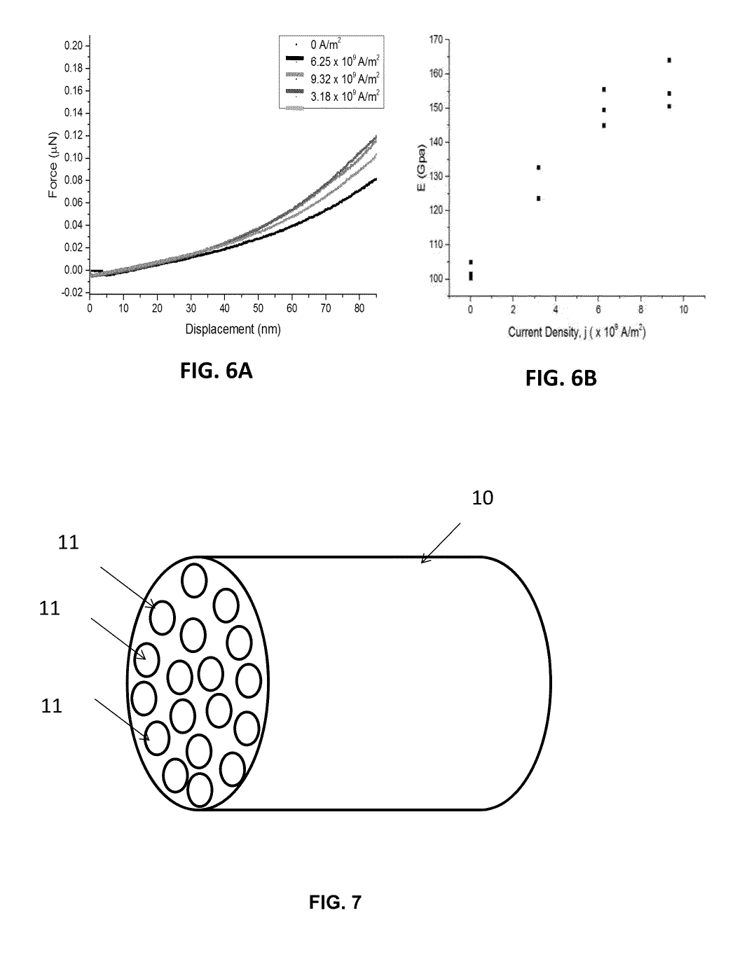

FIG. 6A shows the mechanical behaviour of a 37 nm radius Au nanowire under current. As in the case of Ag nanowires, the effective stiffness of the wires increases with increasing current. This is shown explicitly in FIG. 6B where the Young's modulus from the data in FIG. 6A have been evaluated. Au nanowires are also known to exhibit the same pentagonal twin structure found in Ag nanowires, and hence this behaviour is expected to be prevalent in a wide range of wires, or in beams that have been specifically engineered to have the right combination of interfaces to control the flow of current along the beam.

Computer simulation of the Ag nanowire under current flow reveals two key aspect of the behaviour of the system. Firstly, the current is found to travel preferentially along the wire planes with the largest contribution at the outer edges of the wires, Secondly, the entire wire undergoes a reversible densification under current flow, which is responsible for the enhanced stiffness.

These results suggest that it is possible to specifically engineer beams designed to exhibit current controlled stiffness by embedding a parallel array of metallic wires or filaments along the length of the beam which itself is comprised of a non-conducting material such as a polymer or dielectric. FIG. 7 shows a 3D perspective view of a cylindrical beam 10 with a number of wires 11 embedded along its length. These engineered composite beams provide access to a wide dynamical range of stiffnesses by varying mechanical properties of the polymer/dielectric which is then modulated by current flow through the filaments/wires. This allows for the creation of larger devices, for example for use in Microelectromechanical systems (MEMS) devices.

In addition to applying a steady voltage across the wire to produce a steady current flow and hence a known increase in the wire stiffness, it is also possible to apply a time varying voltage. The resulting current will change directions is response to the applied voltage and as the frequency in increased the current will be confined increasingly to the outer regions of the wires as a result of the well-known skin-depth phenomenon of AC current flow in conductors. This further confinement of the current is expected allow even large increases in stiffness, providing a larger dynamic range of operation.

The incorporation of nanoscale components with similar internal structures will enable a variety of different applications from transparent, flexible electrodes and individual NEMS devices to accelerometers. The stiffening of the nanoscale component in NEMs devices will increases the natural resonance frequency and hence the bandwidth of operation.

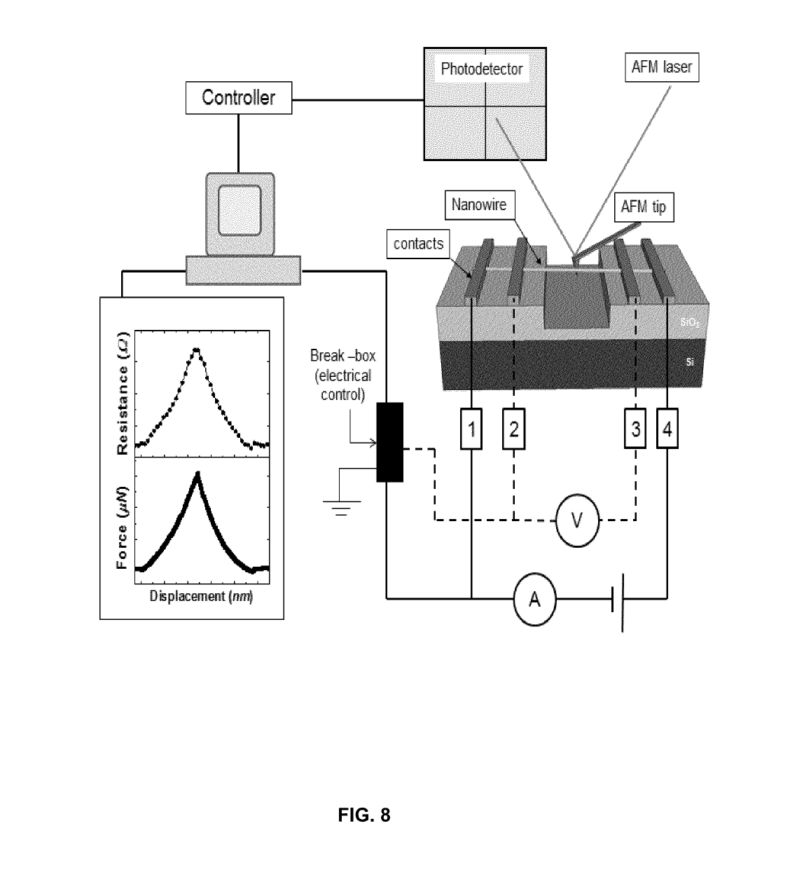

FIG. 8 illustrates a schematic system to measure the change in stiffness of one or more nanowires, such as silver or gold nanowires. The AFM allows for accurate mechanical characterisation by lowering the AFM tip below the axis of the nanowire, into a predefined trench, and laterally driving the tip in the x-y plane perpendicular to the nanowire long axis until the AFM tip loads the nanowire. During loading the torsional motion of the AFM is recorded by the AFM laser-photodetector signal. The contacts, labelled 1-4, allow for 4-point resistance measurement; voltage is sourced and the current is measured across the outermost contacts 1 and 4. The voltage drop across the nanowire is measured across the inner two contacts 2 and 3. The lateral signal from the AFM tip torsional motion during nanowire (NW) loading is measured in unison with the 4-point resistance giving resistance- and force-displacement curves. The break box allows the user to control each electrical contact individually.

It will be appreciated that the invention can be applied to any NEM device for integration of electrical and mechanical functionality on the nanoscale, for example integration of nanoelectronics with mechanical actuators, pumps, or motors and the like, and form other devices such as physical, biological and/or chemical sensors. While Ag and Au nanoscale wires/component have been hereinbefore described, other materials having a single crystal wire with a twinning structure can also be used to enable the invention.

The embodiments in the invention described with reference to the drawings comprise of look-up charts and calculations. However, the invention also extends to computer apparatus and/or processes performed in a computer apparatus, computer programs, particularly computer programs stored on or in a carrier adapted to bring the invention into practice. The program may be in the is form of source code, object code, or a code intermediate source and object code, such as in partially compiled form or in any other form suitable for use in the implementation of the method according to the invention. The carrier may comprise a storage medium such as ROM, e.g. CD ROM, or magnetic recording medium, e.g. a memory stick or hard disk. The carrier may be an electrical or optical signal which may be transmitted via an electrical or an optical cable or by radio or other means.

In the specification the terms “comprise, comprises, comprised and comprising” or any variation thereof and the terms include, includes, included and including” or any variation thereof are considered to be totally interchangeable and they should all be afforded the widest possible interpretation and vice versa.

The invention is not limited to the embodiments hereinbefore described but may be varied in both construction and detail.

1. A method to control the mechanical stiffness of a nanoscale component comprising the steps of:
applying a current to the nanoscale component;
increasing or decreasing the mechanical stiffness of the material by controlling the current flow applied to the component.

2. The method of claim 1 comprising the step of increasing the energy stored in the component by increasing the current flowing through the component.

3. The method of claim 2 wherein the energy stored can be represented by a spring constant value.

4. The method of claim 2 wherein the energy stored exceeds that of the original component, such that the stored energy can assist in the mechanical release of the component when acting as a switch.

5. The method of claim 1 wherein the current applied is an alternating current (AC) current.

6. The method of claim 1 wherein the current applied is a direct current (DC) current.

7. A system for controlling the mechanical stiffness of a nanoscale component comprising:
a source for applying a current to the nanoscale component;
a controller for increasing or decreasing the mechanical stiffness of the material by controlling the current flow applied to the component.

8. The system of claim 7 wherein the controller is configured to control the energy stored in the component by increasing the current flowing through the component.

9. The system of claim 8 wherein the energy stored can be represented by a spring constant value.

10. The system of claim 8 wherein the energy stored exceeds that of the original component, such that the stored energy is configured to assist in the mechanical release of the component when acting as a switch.

11. The system of claim 7 wherein the nanoscale component comprises a NanoElectroMechanical (NEMs) device.

12. The system of claim 7 wherein the current applied is an alternating current (AC) current.

13. The system of claim 7 wherein the current applied is a direct current (DC) current.

14. A NanoElectroMechanical (NEMs) device comprising a controlled mechanical stiffness.

15. The device of claim 14 wherein the mechanical stiffness is controlled by an applied current.

16. A method to control the mechanical stiffness of a nanoscale component comprising the steps of:
applying a voltage to the nanoscale component;
increasing or decreasing the mechanical stiffness of the material by controlling the voltage flow applied to the component.

17. A system for controlling the mechanical stiffness of a nanoscale component comprising:
a source for applying a voltage to the nanoscale component;
a controller for increasing or decreasing the mechanical stiffness of the material by controlling the voltage flow applied to the component.
